(19) United States
(12) Patent Application Publication
(10) Pub. No.: US 2018/0337514 A1
(43) Pub. Date: Nov. 22, 2018

(54) SPECKLE REDUCED BROADBAND VISIBLE QUANTUM DOT LASERS

(71) Applicant: National Research Council of Canada, Ottawa (CA)

(72) Inventors: Haipeng Tang, Ottawa (CA); Li Li, Orleans (CA)

(21) Appl. No.: 15/980,976

(22) Filed: May 16, 2018

Related U.S. Application Data
(60) Provisional application No. 62/507,403, filed on May 17, 2017.

(51) Int. Cl. H01S 5/34; H01S 5/20; H01S 5/32; H01S 5/343; H01S 5/30; H01S 5/183

(52) U.S. Cl. CPC H01S 5/3412; H01S 5/2009; H01S 5/183; H01S 5/34333; H01S 5/3013; H01S 5/3211

(57) ABSTRACT

A semiconductor visible laser with broadband emission and reduced speckling is provided. Conventional lasers with narrow spectral emission cause undesired speckles. The invention reduces laser speckles by producing a broadband laser emission. The laser comprises a multitude of quantum dot layers having quantum dots that have inhomogeneity in size, density, or composition. Methods of constructing such a laser are also provided.

### CROSS-REFERENCE TO RELATED APPLICATIONS

This application claims priority to, and the benefit of, U.S. Provisional Application No. 62/507,403, filed on May 17, 2017, and entitled “SPECKLE REDUCED BROADBAND VISIBLE QUANTUM DOT LASERS,” which is incorporated by reference as if set forth herein in its entirety.

### FIELD OF INVENTION

This invention relates to the field of lasers, and more specifically to broadband semiconductor quantum-dot lasers with reduced speckles for lighting applications.

### BACKGROUND

Lasers are desirable light sources for many applications because of their unique properties. For example, in electronic displays such as LCDs, purer or more saturated colours with a large colour gamut are always desirable. It is difficult to achieve a large colour gamut with commonly used broadband light sources such as arc lamps or light emitting diodes (LED). Lasers, however, can produce purer colours at ease owning to their inherited narrow spectral bandwidths. With their highly-directional light beams, lasers also have the smallest etendue among all light sources. The etendue is a property of a light source that measures the spreading of a light beam in both emitting area and emitting solid angel, and is a major factor that determines the design of an optical system. The etendue of any light sources or optical systems can only be enlarged and cannot be reduced without loss of energy. The use of lasers as light sources in an optical system allows a small etendue together with reduced size, complexity, and costs of the optical system. Furthermore, lasers, especially semiconductor lasers, are compact and highly efficient, and are very useful for lighting applications, such as light sources for instrument illumination or headlights for automobiles.

Unfortunately, for many applications, including those described above, lasers also have a big drawback: they produce speckles—random high and low light intensity patterns when illuminating on surfaces that are not optically smooth, such as a projector screen that is illuminated with a single coherent light source with a narrow spectral bandwidth. Laser speckles are caused by the interference of multiple scattered laser beams from the same narrow-line laser source. Laser speckles constitute an omnipresent adverse effect for many laser applications and significantly limit the uses of lasers even though they are desirable for many applications. For example, speckles cause poor image quality in electronic displays, non-uniform illumination in instrument lightings, or unreadable road signs in automobile headlights.

Many efforts have been made to reduce speckles in the past, and all the approaches are essentially based on the principles first described by J. W. Goodman, “Some fundamental properties of speckle*”, J. Opt. Soc. Am. 66, 1145-1150 (1976), namely, by means of introducing time, space, frequency or wavelength, or polarization diversity, or the combinations of them. However, none of the existing approaches can address the speckle problems at the root—the narrow spectral bandwidth. In addition, many solutions are application specific and they often have serious drawbacks.

The approach of increasing time or spatial diversity is commonly used to reduce laser speckles. An example is laser projection displays, in which high-speed rotating or vibrating diffusers or vibrating screens are employed to average speckles in order to smooth out the speckles. Such approaches clearly increase the system complexity, size and unreliability, and are not desirable or practical for many applications where the additions of moving mechanical components are not realistic. For example, in pico-projectors for cell phones—one of the most promising applications of lasers for displays—mechanical moving diffusers are not practical to deploy. Furthermore, the use of diffusers significantly increases the angular spreading of the laser beams and thus increases the etendue of the laser significantly. As a result, the use of diffusers often defies the very advantage of lasers being used in these applications in the first place (small etendue or highly directional beam to simplify optical systems), and diminishes the gain of using lasers. In addition, because of the spreading of light, a big portion of laser light cannot be collected by the optical systems and results in light loss.

In principle, the approach of increasing wavelength diversity to reduce laser speckles can be achieved by combining individual lasers with different wavelengths. For example, in high power and large screen digital cinema projectors, the use of a large number of individual laser diodes are necessary in order to achieve the required high power since individual diode lasers do not have the required high power. By doing so, the etendue of the optical system is increased, but this is acceptable for digital cinema projectors where large panel sizes are used. However, this approach is not suitable for many applications where a single or a small number of individual lasers is needed, as in home cinema or micro-projectors. In a similar approach, multiple lasers emitting different wavelengths can be fabricated on the same laser bar. However, regardless of how the multiple lasers are combined, the etendue of such an approach always increases. The overall etendue is at least the sum of those of the individual lasers and the resulting etendue is significantly larger than that of a single laser source. For many applications, the increase of etendue is not desirable as it increases the complexity, size, and cost of the employed optical systems.

Therefore, it would be desirable to have a single semiconductor laser that can emit multiple wavelengths or a broad spectral broadband to increase wavelength diversity and thus reduce speckles, unlike those techniques described above that simply combine multiple individual lasers together. In this case, the etendue of the laser device remains small, just like a single wavelength diode laser. In addition, the single laser solution is much more compact and easier to control and operate. To effectively reduce laser speckles, the bandwidth of the lasers is preferably 5 nm or larger. Unfortunately, in the visible part of the spectrum, the currently available semiconductor lasers have a bandwidth of less than 2 nm, and this bandwidth is not enough to reduce speckles. Even worse, in the green part of the visible spectrum where human eyes are most sensitive and the green laser provides most of optical power, the available green lasers have an even narrower bandwidth of about 0.1 nm than conventional laser diodes because they are based on a frequency doubling scheme.

Broadband of quantum dot lasers have been reported for the infrared spectral regions of 1300 nm and 1550 nm using InAs/GaAs and InAs/InGaAsP in Z. O. Lu (Ottawa, CA), Liu, Jiaren (Ottawa, CA), Raymond, Sylvain (Ottawa, CA), Poole, Philip (Ottawa, CA), Barrios, Pedro (Ottawa, CA), Poitras, Daniel (Ottawa, CA), “Quantum dot based semiconductor waveguide devices”, (2010) and S. Mokkapati, S. Du, M. Buda, L. Fu, H. H. Tan, and C. Jagadish, “Multiple Wavelength InGaAs Quantum Dot Lasers Using Ion Implantation Induced Intermixing”, Nanoscale Research Letters 2, 550-553 (2007). However, these semiconductor materials do not emit light in the visible spectral region from 400 nm to 700 nm and thus are not suitable for visible lasers. In the visible region, GaN and InGaN are the desirable semiconductor materials due to bandgaps being in the visible part of the spectrum. However, no broadband GaN based visible lasers have been reported. The InGaN/GaN quantum dot lasers, as disclosed in U.S. Pat. No. 9,362,719 by Bhattacharya et al., have an emission bandwidth less than 1 nm, worse than the 2 nm bandwidth of conventional laser diodes. As a result, there is no practical solution available today for single visible laser devices to reduce speckles using wavelength diversity. Laser speckles remain a big obstacle in expanding the use of lasers for many lighting and imaging applications, including electronic displays, lighting for instruments, general light, and headlights in automobiles.

### SUMMARY

The first objective of the present invention is to provide semiconductor gain materials with proper broadband gain profile to allow broadband lasing.

The second objective of the present invention is to incorporate such broad gain semiconductor materials in different laser structures to achieve broadband lasing.

The third objective of the present invention is to provide different laser devices with either optically pumped or electrically pumped, edge emitting or surface emitting to suit different applications.

### BRIEF DESCRIPTION OF THE DRAWINGS

The features and advantages of embodiments of the invention will become more apparent from the following detailed description of the preferred embodiment(s) with reference to the attached figures, wherein:

FIG. 1 shows a photo-luminescent device having InGaN quantum-dot structure for photoluminescence studies according to one embodiment of the invention;

FIG. 2 shows a transmission electron microscope (TEM) image of InGaN quantum dots in a GaN matrix, the circled areas being the InGaN quantum dots;

FIGS. 3a, 3b, and 3c show the measured photoluminescence spectra of InGaN quantum dot layers grown at temperatures of 680° C., 670° C., and 660° C.;

FIGS. 4a and 4b show the cross-sectional and side views of optically pumped edge emitting laser device in the present invention according to one embodiment of the invention;

FIG. 5 shows the emission intensity versus optical pumping power density for a broadband visible laser according to one embodiment of the invention;

FIG. 6 shows the measured spectrum of the broadband optically pumped edge emitting blue laser according to one embodiment of the invention having a bandwidth of 15 nm;

FIGS. 7a and 7b show a comparison of laser speckles in lasers spots projected on papers from a narrow-band red pointer laser and from blue optically pumped broadband blue laser according to one embodiment of the invention;

FIG. 8 shows the cross-sectional view of an optically pumped surface emitting laser device according to another embodiment of the invention;

FIGS. 9a and 9b show the cross-sectional and side views of an electrically pumped edge emitting laser device according to another embodiment of the invention; and

FIG. 10 shows the cross-sectional of an electrically pumped surface emitting laser device according to another embodiment of the invention.

It is noted that in the attached figures, like features bear similar labels.

### DETAILED DESCRIPTION OF THE PREFERRED EMBODIMENTS

### Photoluminescence of Quantum Dots

One of the important aspects of the broadband lasers of the invention is to produce an optical gain medium, which can emit a broadband photoluminescence, a first and a necessary step to obtain broadband laser emission. The semiconductor InGaN is selected as the first optical gain medium since InGaN is a ternary compound semiconductor and its bandgap can be tuned to cover the entire visible spectrum by varying the ratio of In to Ga, or the factor x when using a more depicted formula InₓGaₓ₋₁N. To broaden the bandgap for making broadband lasers, InGaN quantum dots with proper properties (size, compositions or densities) are used. Unlike bulk or quantum-well semiconductor active medium, the bandgap of quantum dots as well as their optical gain are the functions of the composition of the dots, their size, shapes and distributions, the dot density, etc. To achieve the desired emission spectral bandwidth (at least 2 nm, more preferably 2.5 nm, 4 nm, 4.5 nm, or 5 nm), it is critical to fabricate proper quantum dots to have the right optical properties. Otherwise, even if quantum dots are used in the laser structures, it is not possible to obtain broadband laser emission, as disclosed by Bhattacharya, in which the bandwidth of their lasers are 1 nm or less.

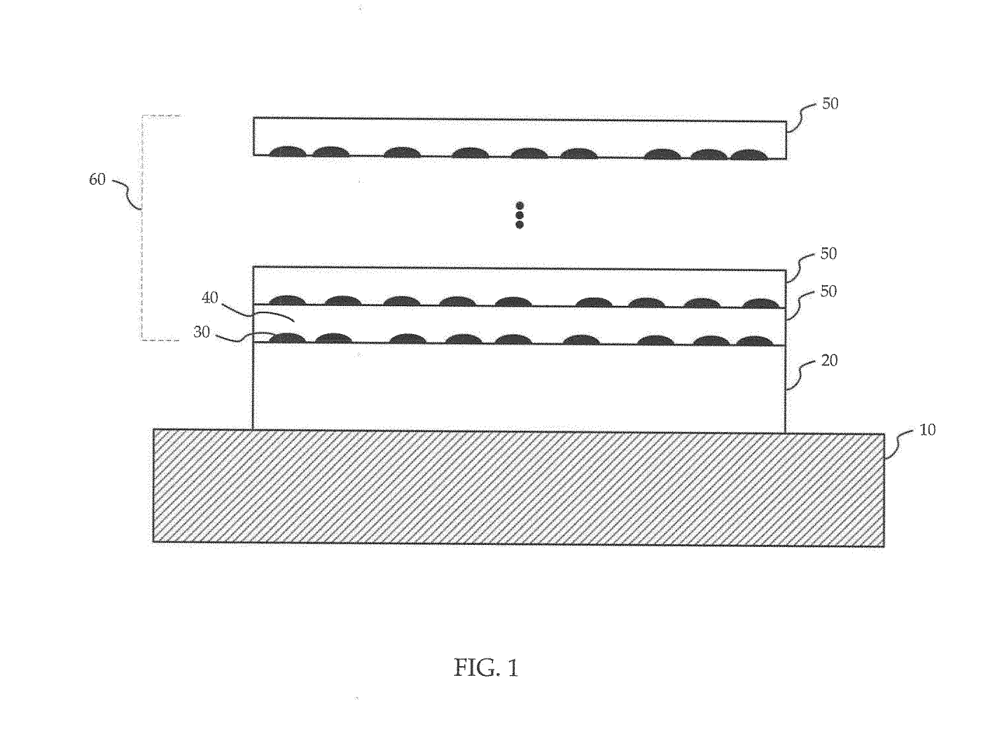

To demonstrate the broad emission optical properties of InGaN quantum dots, different intermediate photo-luminescent devices are fabricated with a structure shown in FIG. 1. The photo-luminescent device comprises a substrate 10 made of GaN, sapphire, SiN, or SiC, an optional Si:GaN buffer layer 20 if the substrate is not GaN or the substrate has defects, an active optical gain medium 60 having multiple periods of a quantum dot layer pair 50, including a InₓGa₁₋ₓN quantum dot layer 30 and a GaN barrier layer 40. The buffer layer 20 of Si:GaN is used to match the crystal lattice of the substrate 10 and the active layers.

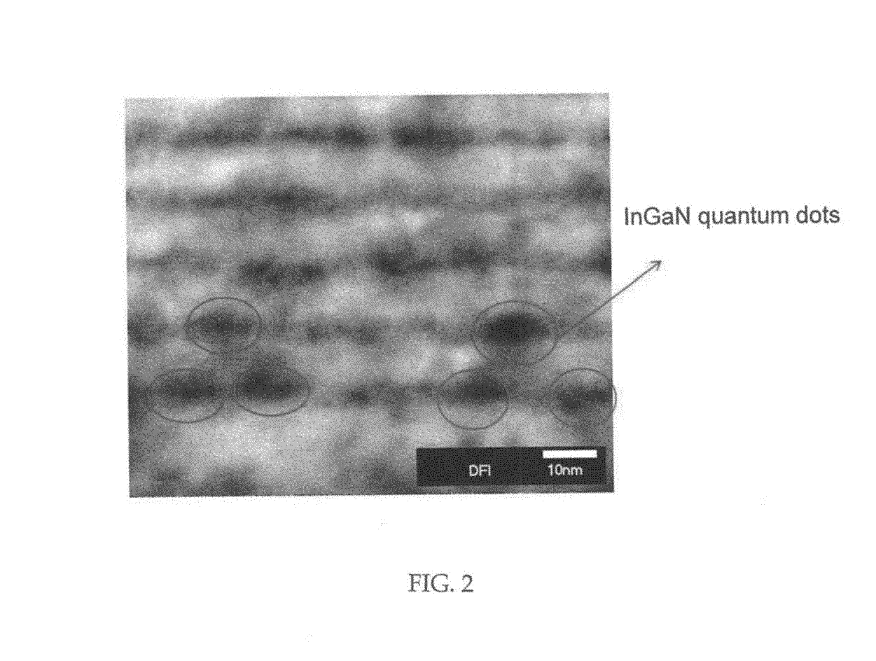

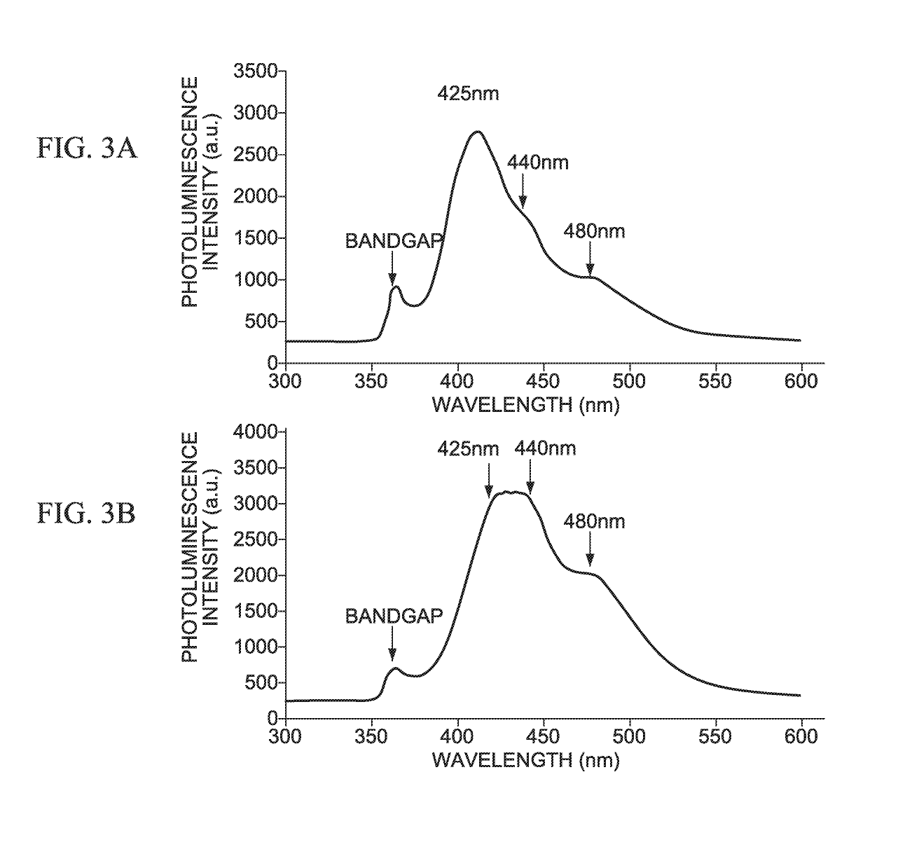

The InₓGa₁₋ₓiN quantum dots are grown by RF-plasma molecular-beam epitaxy (MBE). Other film growth methods such chemical vapour deposition (CVD) can also be used to produce the quantum dots. FIG. 2 shows the cross-section of the photo-luminescent device, in which, the InₓGa₁₋ₓN quantum dot layers and the barrier layers have a typical thickness of 3 nm and 7 nm, respectively. The photo-luminescent device has 10 periods of quantum dot layer pairs. Different quantum dot layer thicknesses and barrier layer thicknesses as well as periods can be used as well. The InₓGa₁₋ₓN quantum dots are clearly visible (dark circled areas) in FIG. 2. The light emission properties of the photo-luminescent devices grown under different growth conditions were characterized by photoluminescence at room temperature as shown in FIGS. 3a, 3b and 3c for different growth conditions. FIG. 3a shows the measured photoluminescence spectra of InGaN quantum dot layers grown at a temperature of 680° C., FIG. 3b shows the measured photoluminescence spectra of InGaN quantum dot layers grown at a temperature of 670° C., and FIG. 3c shows the measured photoluminescence spectra of InGaN quantum dot layers grown at a temperature of 660° C. As seen in the figures, the photo-luminescent emission spectra are much broader than that of GaN or a single composition of InGaN. The broad photo-luminescent spectrum is a good indication that a wide gain active medium is obtained, and thus the potential for broadband lasing.

The broadening of the gain spectrum of InGaN quantum dots is induced by both the inhomogeneity of the quantum dot size as well as by compositional inhomogeneity. The size randomness can be clearly seen in FIG. 2 of the TEM picture of the active medium. This phenomenon is different from the binary compound semiconductor quantum dots such as the InAs quantum dots where the gain broadening is only induced by quantum size randomness, as in the IR quantum dot lasers as disclosed by Lu.

The quantum dot size inhomogeneity is achieved in the present invention by the III/V ratio, growth temperature, and growth time and growth interruption. Due to the strained growth of InGaN on GaN, formation of InGaN quantum dots can occur via the Stranski-Krastanov mechanism, especially under nitrogen rich and low temperature growth conditions. Growth interruption at the completion of InGaN growth can also alter the quantum dot size distribution.

The compositional inhomogeneity of InGaN quantum dots during the growth are controlled by two effects: (i) phase segregation, and (ii) composition pulling effect. The phase segregation is due to the low miscibility of InN and GaN at the MBE growth temperature range. The composition pulling effect refers to the strain induced inhibition of indium incorporation at the growth front. Its consequence is non-uniform (increasing) indium concentration along the direction of the growth. As a result, the indium concentration varies slightly from one quantum dot layer to the following quantum dot layer in a structure as shown in FIG. 1.

The compositional inhomogeneity of the InGaN quantum dots within the same layer is controlled by deposition parameters, including the growth temperature, the energy of neutral nitrogen radicals, and the ion content in the nitrogen flux. Compositional phase separation becomes progressively dramatic with higher growth temperature, lower energy nitrogen radicals, and higher ionic content. In addition, the compositional difference between phase A and phase B decreases with increasing energy of the nitrogen radicals and with decreasing ionic content in the nitrogen flux. The neutral radicals refer to atomic nitrogen and excited nitrogen molecules whose energy is controlled by the plasma power and the nitrogen gas flow. The ionic content in the nitrogen flux is regulated by using an electric field deflection mechanism. A growth parameters paradigm is thus established which allows the overall compositional inhomogeneity to be tuned to the desired range in order to achieve the required gain bandwidth. The growth temperature range is varied from a low of 620° C. to a high of 680° C.

The three devices for which the photoluminescence spectra are shown in FIG. 3 were grown under identical plasma condition but different growth temperatures. All the spectra show multiple emission peaks attributed to multiples phases formed by phase segregation. As shown in FIG. 3a, at the higher growth temperature of 680° C., the dominant phase emits at 425 nm, with shoulder emissions at 440 nm and 480 nm. In FIG. 3b, at growth temperature of 670° C., the phase emitting at 425 nm and the phase emitting at 440 nm become equal in intensity, and thus forming a broad and flat emission band. In FIG. 3c, as the growth temperature is reduced further to 660° C., the 425 nm phase is suppressed, and the 440 nm and 480 nm phases become most prominent. The photoluminescence devices show that by choosing suitable growth parameters, the compositional phases of the InGaN quantum dots can be tuned, which ultimately determine the width of the gain profile. Even for single-compositional-phase quantum dots, the gain profile is also broadened by the quantum size inhomogeneity. However, the phase inhomogeneity has the potential to broaden the gain profile further.

Many other photo-luminescent devices having different quantum dot layer thickness, barrier layer thickness, number of periods, or other growth conditions have also been fabricated and they all showed broadband emission at different wavelengths.

With the success in obtaining broadband gain medium based on quantum dots, it is now possible to make broadband semiconductor lasers to reduce lasers speckles, in accordance with the present invention. In the following text, four different embodiments of the broadband lasers of the present invention will be described in detail.

### EMBODIMENTS

In accordance with the present invention, the embodiments disclosed herein are designed to ensure that the broadband quantum-dot gain medium is incorporated in proper cavity structures so that lasing conditions can be satisfied and laser light can be emitted from either the edge or surface of the laser devices.

### Embodiment 1—Optically Pumped Quantum Dot Lasers Having Edge Emitting Light

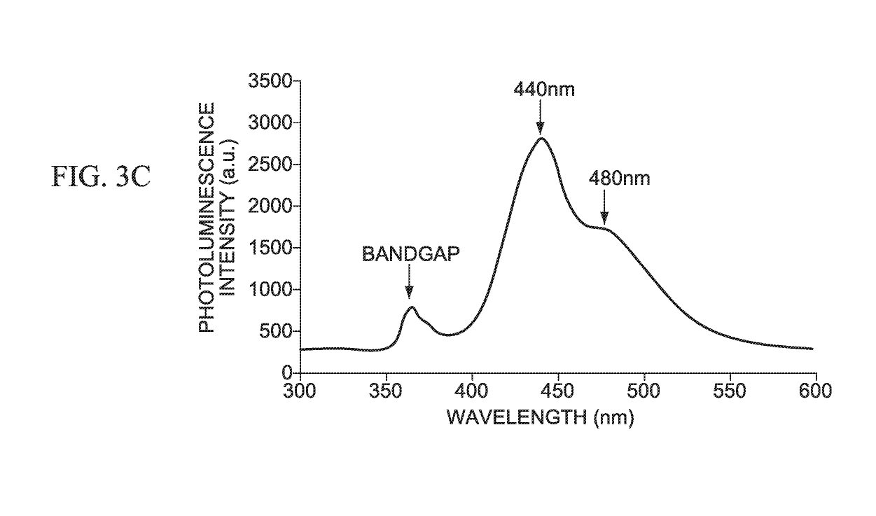

The first embodiment of the present invention is an optically pumped edge emitting quantum dot laser in a waveguide format and has a bandwidth at least 2 nm or higher. The schematic diagram of the laser device of this embodiment is shown in a cross-sectional view in FIG. 4a and a side view in FIG. 4b. The laser device comprises a substrate 410, selected from GaN, SiN, SiC, or sapphire; an optional buffer layer 420; an active medium 460 having multiple periods of quantum dot layer pairs 450, each consisting of a quantum dot layer 430 and a barrier layer 440. The substrate 410, buffer layer 420, active medium 460, and quantum dot layer pairs 450 are similar to those described above with reference to FIG. 1. The laser device of this embodiment also comprises a bottom waveguide layer 470 and a top waveguide layer 475; a bottom cladding layer 480 and a top cladding layer 485, each with a lower refractive index than that of the waveguide layers 470 and 475; an optional top protecting layer 490; an optional mirror coating 494 with a reflectance between 30% and 100% at the one end of the edge; and an optional partial transmissive and partial reflective mirror coating 496 at the other end of the edge for laser output. The optional buffer layer 420 is used to match the crystal lattice of the substrate 410 and other layers in the laser device if the crystal structure of the substrate is different from that of the other layers.

In operation, the device is illuminated with a shortwave light such as UV light from the top, bottom, or both. The UV light is absorbed by the gain medium to achieve the required population inversion for lasing. The laser cavity is formed by the two end surfaces or facets of the device having two optional mirror coatings. Since the semiconductor materials in the cavity have higher refractive index than the exit medium air, in some cases, the simply cleaved facets would have adequate reflection to provide the needed feedback for lasing. Cleaving is a common method used in the semiconductor industry to obtain a clean facet by splitting a crystal or crystalline substrate using a force along its plane with weaker chemical bonds in the crystal structure. However, the two optional mirror coatings are preferred since they can reduce the loss and thus reduce the lasing threshold and increase the efficiency of the device. The mirror coatings are made of metal or dielectric layers. The laser light is emitted from the edge, i.e. from at least one of the two facets. Since the cavity length of the laser device is rather long, in the range of tens microns to a few millimeters, the device can support many longitudinal modes with different wavelengths.

One working example of the first embodiment has InGaN quantum dots described above as the gain media, 10 periods of quantum dot layer pairs, two GaN waveguide layers about 100 nm in thickness, a 600 nm bottom cladding layer AlGaN, and 300 nm top cladding AlGaN layer. The structures were grown on a substrate made of HVPE bulk GaN templates with (10×10.5 mm) dimension and dislocation density of less than 1E6 cm⁻². After growth, the laser wafers were cleaved into laser bars with cavity length of about 1 mm

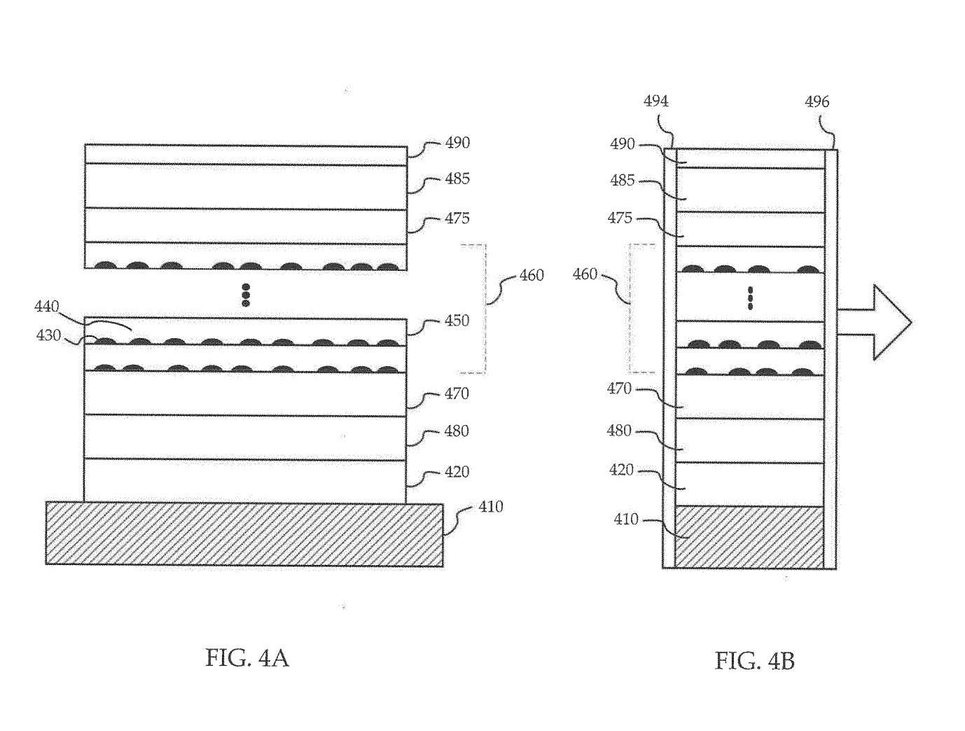

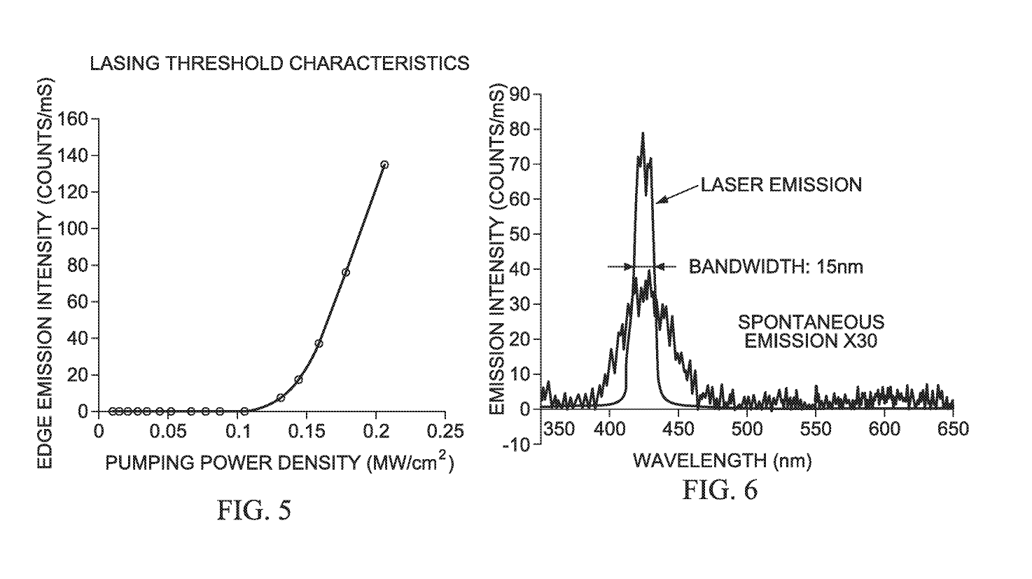

The laser bars were optically pumped using a pulsed YAG laser at 355 nm having 10 ns pulses and 10 Hz repetition rate. The pumping beam was focused by a cylindrical lens to form a narrow stripe across the laser bar. The edge emission was detected by a CCD spectrometer. FIG. 5 shows the emission intensity versus optical pumping power showing typical lasing characteristics with a rapid increase in emission light intensity beyond the lasing threshold. Below the lasing threshold, the emission is spontaneous with a broad spectrum but has a low intensity that increases linearly with the pumping power or power density. Once the power density reaches the lasing threshold, the output light intensity increases significantly and the emission shows a typical laser characteristics with a far field light distribution close to predicted by theoretical simulations. However, unlike a typical semiconductor laser having a spectral bandwidth about 2 nm or less, the spectrum of the device in the present invention has a much broader spectral bandwidth, in this particular case about 15 nm as shown in FIG. 6.

Other examples of the optically pumped broadband visible laser in accordance with the present invention have also be fabricated with lasing wavelengths in the blue and green regions of the visible spectrum, and have spectral bandwidth values typically in the range of 5 nm to 15 nm.

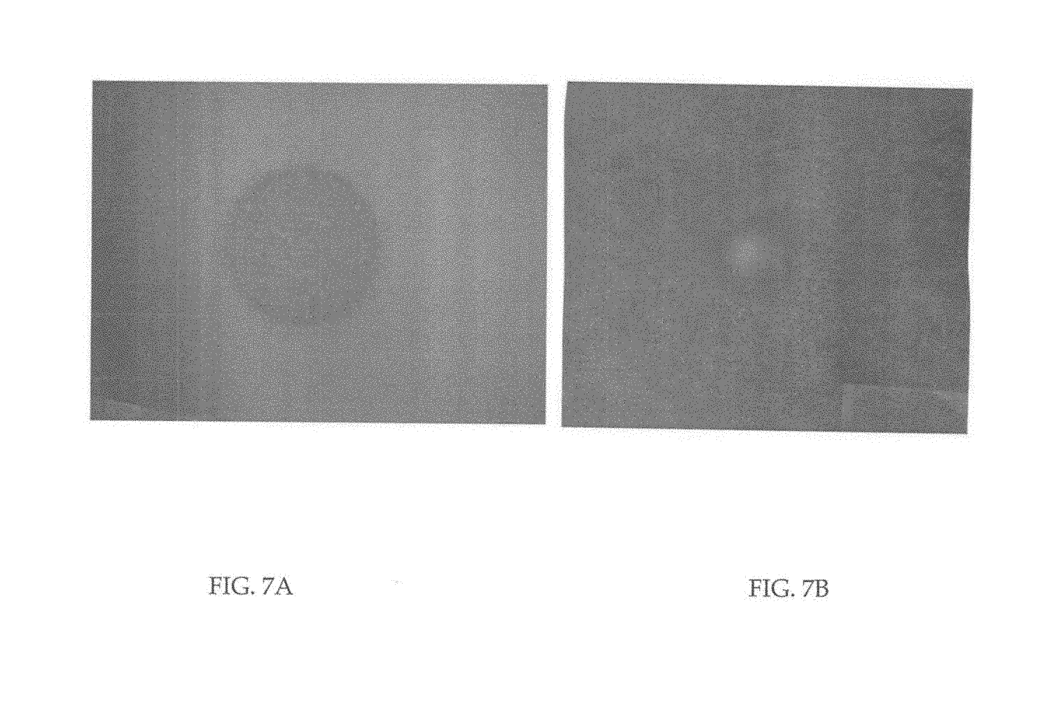

A preliminary examination of the speckle reduction effect of the broadband lasers in the present invention was demonstrated in comparison with a conventional red semiconductor laser diode having a spectral bandwidth less than 2 nm. When the red laser beam is illuminated on a piece of paper with an optically rough surface, the photographed laser spot on the paper has prominent speckles as shown in FIG. 7a. In contrast, when the optically pumped lasers with bandwidth of 8 nm to 15 nm in accordance with the present embodiment was illuminated on the same piece of paper, the laser spot, as shown in FIG. 7b, is more uniformed and smoother, with no prominent speckles. Other photographs of reduced speckles were also demonstrated with the broadband lasers disclosed in the present invention.

### Embodiment 2—Optically Pumped Quantum Dot Lasers Having Surface Emitting Light

For some applications, surface emitting lasers are more desirable since the emitted light has a circular angular distribution and it can be easily coupled into other optical components. A second embodiment of the present invention is an optically pumped surface emitting quantum dot laser and has a bandwidth at least 2 nm or higher. Unlike the edge emitting laser structured described above, the optical gain medium in the second embodiment is sandwiched between two reflectors with high reflectance to form the necessary feedback requirement.

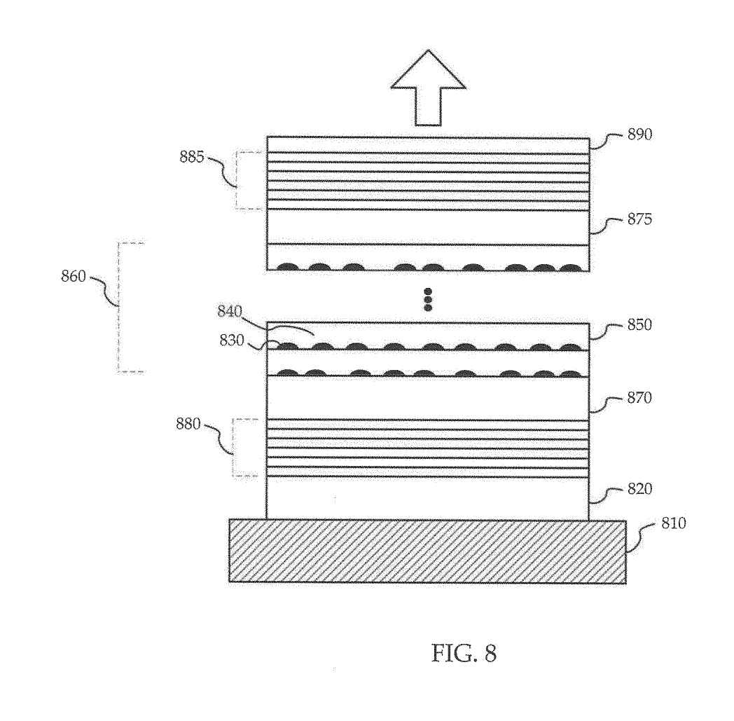

The schematic diagram of the laser device of the second embodiment is shown in a cross-sectional view in FIG. 8. The laser device comprises a substrate 810, selected from GaN, SiN, SiC, or sapphire; an optional buffer layer 820; an active medium 860 having multiple periods of quantum dot layer pairs 850 of a quantum dot layer 830 and a barrier layer 840. The substrate 810, optional buffer layer 820, active medium 860, and quantum dot layer pairs 850 are similar to those described above with reference to FIG. 1. The laser device of this embodiment also comprises a bottom cavity layer 870 and a top cavity layer 875; a bottom mirror coating 880; a top mirror coating 885; and an optional top protecting layer 890.

In operation, the device is illuminated with a shortwave light such as UV light from the top, bottom, or both. The top and bottom mirror coatings are designed to allow the pumping laser light having short wavelengths to pass through the mirror structure so that the light can reach the active gain medium in the centre. The UV light is absorbed by the gain medium to achieve the required population inversion for lasing. The laser cavity is formed by the top and bottom mirrors. The bottom mirror can be made of high and low index semiconductor layers which are compatible with the fabrication of the active laser structures. The top mirror can be made with similar coating materials as the bottom mirror coating or conventional all-dielectric coatings. The laser light is emitted from the top surface or the bottom surface, depending on which mirror coating has partial transmissivity for the lasing wavelength. The mirror coating on the side that the light emits should have a not too high reflectance so that the structure can support multiple wavelength lasing.

### Embodiment 3—Electrically Pumped Quantum Dot Lasers Having Edge Emitting Light

For many applications, electrically pumped lasers are more desirable because of their simplicity, compactness, and higher efficiency. The third embodiment of the present invention is an electrically pumped edge emitting quantum dot laser in a waveguide format and has a bandwidth at least 2 nm or higher. Unlike the optically pumped structures, which require the use of a short wavelength pumping light source, the electrically pumped lasers in the present invention use electrical current to provide the needed population inversion for lasing. To achieve this purpose, some of the layers in the laser structure must be n-doped or p-doped semiconductors so that electrons and holes move inside the structures. In addition, electrodes are required to introduce current across the laser device structures.

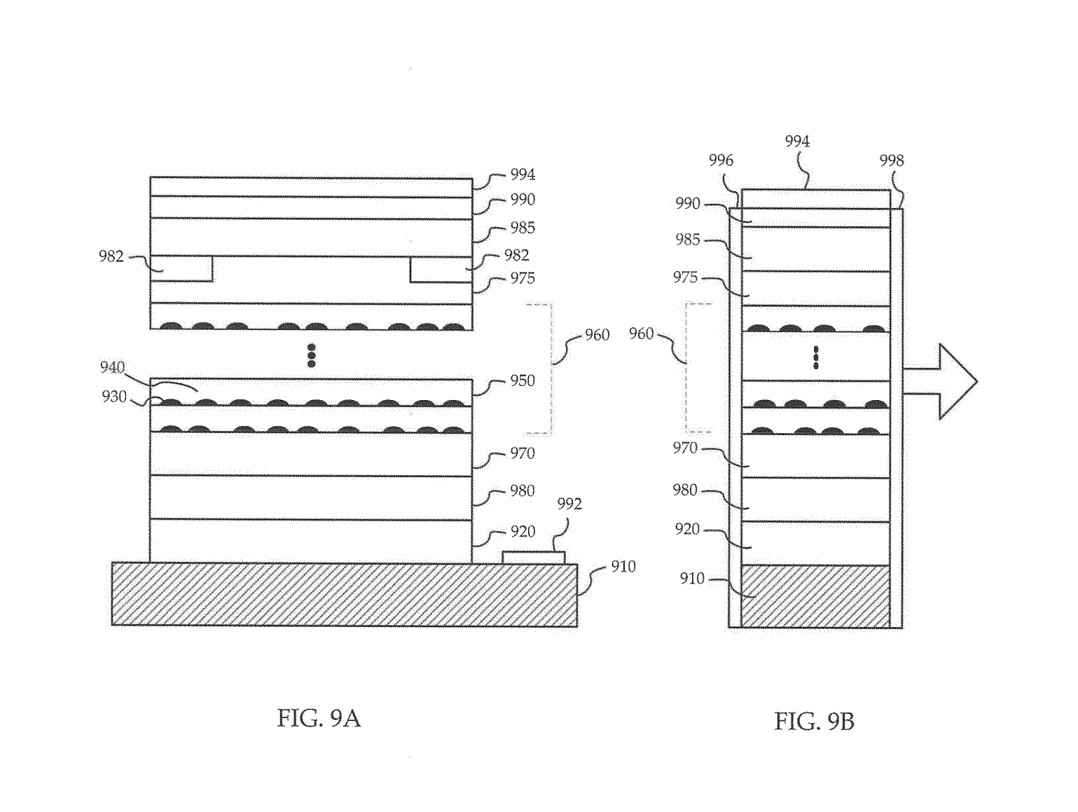

The schematic diagram of the laser device according to a third embodiment is shown in a cross-sectional view in FIG. 9a and a side view in FIG. 9b. The laser device comprises a substrate 910, selected from GaN, SiN, SiC, or sapphire; an optional buffer layer 920; an active medium 960 having multiple periods of quantum dot layer pairs 950 of a quantum dot layer 930 and a barrier layer 940. The substrate 910, optional buffer layer 920, active medium 960, and quantum dot layer pairs 950 are as described above with reference to FIG. 1. The laser device of this embodiment also comprises a bottom waveguide layer 970; a top waveguide layer 975; an insulating layer made of oxide 982; a bottom cladding layer 980 and a top cladding layer 985, both having a lower refractive index than that of the waveguide layers 970 and 975; an optional top protecting layer 990; a bottom electrode 992 and top electrode 994; and an optional mirror coating 996 with a reflectance between 30% and 100% at the one end of the edge and an optional partial transmissive and partial reflective mirror coating 998 at the other end of the edge. The electrodes 992 and 994 are made of metal materials such as gold. Two types of doping are possible: (1) the buffer layer 920 is n-doped, the bottom waveguide layer 970 is n-doped, the top waveguide layer 975 is p-doped, the bottom cladding layer 980 is n-doped, the top cladding layer 985 is p-doped, and the optional top protecting layer 990 is p-doped; or (2) the buffer layer 920 is p-doped, the bottom waveguide layer 970 is p-doped, the top waveguide layer 975 is n-doped, the bottom cladding layer 980 is p-doped, the top cladding layer 985 is n-doped, and the optional top protecting layer 990 is n-doped.

In operation, electrical current is added to the device through the top and bottom electrodes 992 and 994. The moving electrons will excite the gain medium inside the structure to a higher energy state to achieve the required population inversion for lasing. The laser cavity is formed by the two end surfaces or facets of the device having two optional mirror coatings. Since the semiconductor materials in the cavity have higher refractive index than the exit medium air, in some cases the simply cleaved facets would have adequate reflection to provide the needed feedback for lasing. However, the two optional mirror coatings are preferred since they can reduce the loss and thus reduce the lasing threshold and increase the efficiency of the device. The mirror coatings are made of metal or dielectric layers. The laser light is emitted from the edge, i.e. at at least one of the two facets. Since the cavity length of the laser device is rather long, in the range of tens microns to a few millimeters, the device can support many longitudinal modes with different wavelengths.

### Embodiment 4—Electrically Pumped Quantum Dot Lasers Having Surface Emitting Light

As in the case of embodiment 2, for some applications surface emitting lasers are more desirable since the emitted light has a circular angular distribution and it can be easily coupled to other optical components. The fourth embodiment of the present invention is an electrically pumped surface emitting quantum dot laser and has a bandwidth at least 2 nm or higher. Unlike the edge emitting laser structure described above in the third embodiment, the optical gain medium is sandwiched between two reflectors to form the necessary feedback requirement. Unlike the optically pumped structures, which require the use of a short wavelength pumping light source, the electrically pumped lasers in the present invention use electrical current to provide the needed population inversion for lasing. To achieve this purpose, some of the layers in the laser structure must be n-doped or p-doped semiconductors so that electrons and holes can move inside the structures. In addition, electrodes are required to introduce current across the laser device structures.

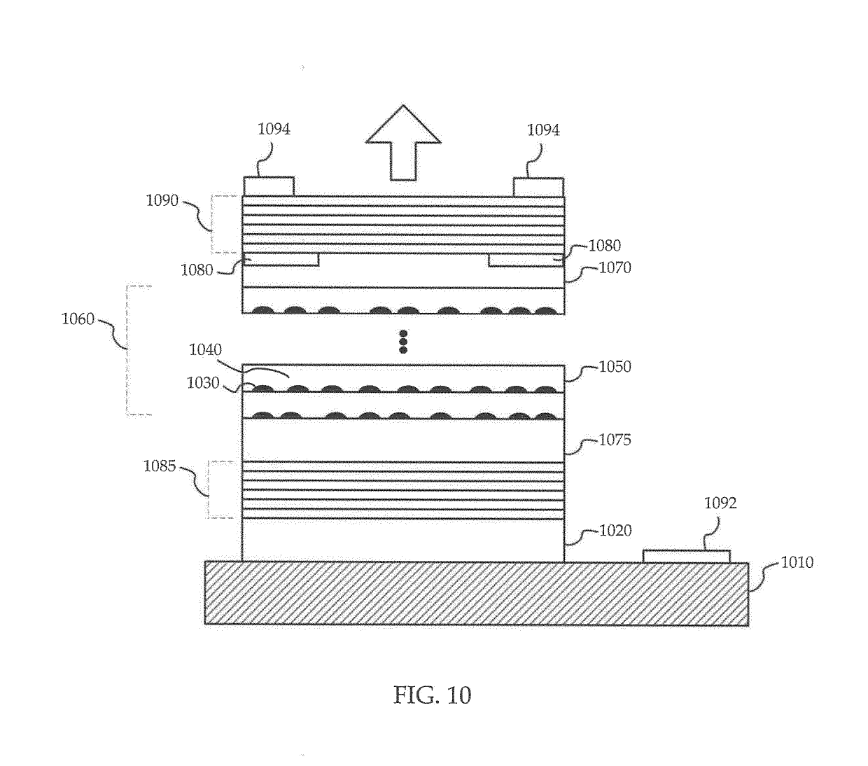

The schematic diagram of the laser device of this embodiment is shown in a cross-sectional view in FIG. 10. The laser device comprises a substrate 1010, selected from GaN, SiN, SiC, or sapphire; an optional buffer layer 1020; an active medium 60 having multiple periods of quantum dot layer pairs 1050 of a quantum dot layer 1030 and a barrier layer 1040. The substrate 1010, optional buffer layer 1020, active medium 1060, and quantum dot layer pairs 1050 are similar to those described above with reference to FIG. 1. The laser device of this embodiment also comprises a top cavity layer 1070; a bottom cavity layer 1075; an insulating layer made of oxide 1080; a bottom mirror coating 1085; a top mirror coating 1090; and a bottom electrode 1092 and an annular top electrode 1094. The electrodes are made of metal materials such as gold. Various layers are made of doped semiconductor, and two types of doping are possible: (1) the buffer layer 1020 is n-doped, the bottom cavity layer 1075 is n-doped, the top cavity layer 1070 is p-doped, the bottom mirror coating 1085 is n-doped, and the top mirror coating 1090 is p-doped; and (2) the buffer layer 1020 is p-doped, the bottom cavity layer 1075 is p-doped, the top cavity layer 1070 is n-doped, the bottom mirror coating 1085 is p-doped, and the top mirror coating 1090 is n-doped.

In operation, electrical current is added to the device through the top and bottom electrodes 1094 and 1092. The moving electrons will excite the gain medium inside the structure to a higher energy state to achieve the required population inversion for lasing. The laser cavity is formed by the top and bottom mirror coatings. The bottom mirror coating 1085 can be made of high and low index semiconductor layers which are compatible with the fabrication of the active laser structures. The top mirror coating 1090 can be made with similar coating materials as the bottom mirror coating 1085 or conventional all-dielectric coatings. The laser light is emitted from the top surface or the bottom surface, depending on which mirror coating has partial transmissivity for the lasing wavelength. The mirror coating on the side that the light emits should have a not too high reflectance so that the structure can support multiple wavelength lasing.

The embodiments presented are exemplary only and persons skilled in the art would appreciate that variations to the embodiments described above may be made without departing from the spirit of the invention. For example, different semiconductor materials whose bandgaps are in the visible spectral region can alternatively be used to make quantum dot lasers as described in the embodiments, or different lasing structures can be used. The scope of the invention is solely defined by the appended claims.

I/We claim:

1. A semiconductor laser, comprising:
a substrate;
an optional buffer layer on the substrate; and
an active optical gain medium on the buffer layer if present, or on the substrate if the buffer layer is not present, the active optical gain medium comprising:
a plurality of quantum dot layer pairs, each pair comprising a quantum dot layer and a barrier layer, the quantum dot layer having quantum dots exhibiting at least one of compositional inhomogeneity, size inhomogeneity, and density variation and enabling the emission of laser light with a spectral bandwidth of at least 2 nm.

2. The semiconductor laser of claim 1 wherein the quantum dots of each quantum dot layer exhibit compositional inhomogeneity, size inhomogeneity, and density variation

3. The semiconductor laser of claim 1 wherein the laser emits laser light from its edge and is optically pumped with at least one light source having a shorter wavelength than the emitted laser light, the semiconductor laser further comprising:
a top waveguide layer above the active optical gain medium and a bottom waveguide layer below the active optical gain medium; and
a top cladding layer and a bottom cladding layer for the top waveguide layer and bottom waveguide layer respectively, each cladding layer being on the side of the respective waveguide layer opposite that of the side adjoining the active optical gain medium, the cladding layers having a lower refractive index than that of the waveguide layers.

4. The semiconductor laser of claim 3 further comprising:
a first mirror coating with a reflectance of between 30% and 100% on one edge of the semiconductor laser; and
a second mirror coating with partial transmissivity on an opposite edge of the semiconductor laser.

5. The semiconductor laser of claim 1 wherein the laser is optically pumped and has surface emitting light, the semiconductor laser further comprising:
a top cavity layer above the active optical gain medium and a bottom cavity layer below the active optical gain medium;
a first mirror coating between the buffer layer and the bottom cavity layer, or between the substrate and the bottom cavity layer if the buffer layer is not present; and
a second mirror coating on the top cavity layer.

6. The semiconductor laser of claim 1 wherein the laser is electrically pumped and has edge emitting light, the semiconductor laser further comprising:
a top waveguide layer above the active optical gain medium and a bottom waveguide layer one below the active optical gain medium;
a top cladding layer and a bottom cladding layer for the top waveguide layer and the bottom waveguide layer repectively, each cladding layer being the side of the respective waveguide layer opposite that of the side adjoining the active optical gain medium, the cladding layers having a lower refractive index than that of the waveguide layers;
a bottom electrode on the substrate; and
a top electrode above the top cladding.

7. The semiconductor laser of claim 6 further comprising:
a first mirror coating with a reflectance of between 30% and 100% on one edge of the semiconductor laser; and
a second mirror coating with partial transmissivity on the opposite edge of the semiconductor laser.

8. The semiconductor laser of claim 1 wherein the laser is electrically pumped and has surface emitting light, the semiconductor laser further comprising:
a top cavity layer above the active optical gain medium and a bottom cavity layer below the active optical gain medium;
a first mirror coating between the buffer layer and the bottom cavity layer or between the substrate and the bottom cavity layer if the buffer layer is not present;
a second mirror coating on the cavity layer which is above the active optical gain medium;
a bottom electrode on the substrate; and
a top electrode above the second mirror coating.

9. The semiconductor laser of claim 1 wherein the quantum dots are InGaN quantum dots and the barrier layers are made of GaN.

10. A method of making a semiconductor laser, comprising:
optionally forming a buffer layer on a substrate; and
forming a plurality of quantum dot layer pairs, on the buffer layer if the buffer layer is present and on the substrate if the buffer layer is not present, as an active optical gain medium, the forming of each quantum dot layer pair comprising:
forming a quantum dot layer having quantum dots exhibiting at least one of compositional inhomogeneity, size inhomogeneity, and density variation and having a broadband of gain profile and a lasing spectral bandwidth of at least 2 nm; and
forming a barrier layer.

11. The method of claim 10 wherein the quantum dots exhibit compositional inhomogeneity, and wherein forming each quantum dot layer includes, during growth of the quantum dot layer, at least one of:
varying a growth temperature;
varying the energy of neutral nitrogen radicals; and
varying the ion content in a nitrogen flux.

12. The method of claim 10 wherein the quantum dots exhibit size inhomogeneity, and wherein forming each quantum dot layer includes, during growth of the quantum dot layer, at least one of:
varying a growth temperature;
varying a growth time;
interrupting growth of the layer are various times; and
varying a III/V ratio of deposited material.

13. The method of claim 12 wherein the quantum dots exhibit compositional inhomogeneity, and wherein forming each quantum dot layer includes, during growth of the quantum dot layer, at least one of:
varying the energy of neutral nitrogen radicals; and
varying the ion content in a nitrogen flux.

14. The method of claim 10 wherein the quantum dots exhibit compositional inhomogeneity, size inhomogeneity, and density variation.

15. The method of claim 14 wherein forming each quantum dot layer includes, during growth of the quantum dot layer, at least one of:
varying a growth temperature;
varying a growth time;
interrupting growth of the layer are various times;
varying a III/V ratio of deposited material;
varying the energy of neutral nitrogen radicals; and
varying the ion content in a nitrogen flux.

16. The method of claim 10 wherein forming each quantum dot layer comprises forming InGaN quantum dots and wherein forming each barrier layer comprises forming a GaN layer.

17. The method of claim 15 wherein forming each quantum dot layer comprises forming InGaN quantum dots and wherein forming each barrier layer comprises forming a GaN layer.
